(19) United States
(12) Patent Application Publication
(10) Pub. No.: US 2025/0194259 A1
(43) Pub. Date: Jun. 12, 2025

(54) SEMICONDUCTOR COMPONENT AND INK JET RECORDING ELEMENT SUBSTRATE

(71) Applicant: CANON KABUSHIKI KAISHA, Tokyo (JP)

(72) Inventors: SUGURU TANIGUCHI, Kanagawa (JP); TOSHIO NEGISHI, Kanagawa (JP)

(21) Appl. No.: 18/967,849

(22) Filed: Dec. 4, 2024

(30) Foreign Application Priority Data
Dec. 12, 2023 (JP) 2023-209476

(51) Int. Cl. H10D 89/60; B41J 2/14; B41J 2/34; H05K 1/02; H05K 1/18

(52) U.S. Cl. CPC H10D 89/60; B41J 2/14201; B41J 2/34; H05K 1/0213; H05K 1/181; H05K 2201/10166

(57) ABSTRACT

A semiconductor component is used which has a semiconductor substrate, a transistor arranged on the semiconductor substrate, and connected with a first terminal with a first potential, an anti-fuse element connected between a second terminal with a second potential different from the first potential and the transistor, and a noise detection circuit electrically connected with respect to the second terminal, and for detecting a noise and outputting a detection signal. The transistor is to be turned off on the basis of the detection signal outputted from the noise detection circuit.

### BACKGROUND OF THE INVENTION

### Field of the Invention

The present invention relates to a semiconductor component and an ink jet recording element substrate.

### Description of the Related Art

A liquid discharge device for discharging a liquid, and performing recording on a recording medium such as paper generally has a liquid discharge head including a substrate. On such a substrate of a liquid discharge head, a semiconductor component including an anti-fuse element may be mounted. The semiconductor component is used for recording the product intrinsic information such as chip ID or setting parameters after completion of the product. The anti-fuse element is also referred to as an OTP (One Time Programmable) memory because of the property of being basically capable of performing recording only one time. For example, Japanese Patent Application Publication No. 2022-138607 shows the configuration using an anti-fuse element.

### SUMMARY OF THE INVENTION

Japanese Patent Application Publication No. 2022-138607 discloses a semiconductor component including a voltage application circuit for supplying a voltage for performing writing on an anti-fuse element. With the voltage application circuit, whether the power supply voltage applied to an electrode pad is applied to an anti-fuse element, or not can be switched by a switching circuit. However, transmission of a high frequency voltage which has entered a surge electrode due to a so-called noise such as a static electricity discharge outside the semiconductor component or lightening surge through the voltage application circuit may cause incorrect writing on the anti-fuse element.

The present invention was completed in view of the foregoing problem. It is an object of the present invention to prevent incorrect writing on an anti-fuse element due to noise intrusion in a semiconductor component having the anti-fuse element.

The present invention provides a semiconductor component comprising:
a semiconductor substrate;
a transistor arranged on the semiconductor substrate, and connected with a first terminal with a first potential;
an anti-fuse element connected between a second terminal with a second potential different from the first potential and the transistor; and
a noise detection circuit electrically connected with respect to the second terminal, and configured to detect a noise and output a detection signal, wherein
the transistor is turned off on the basis of the detection signal outputted from the noise detection circuit.

The present invention also provides an ink jet recording element substrate comprising:
a semiconductor substrate;
a semiconductor component arranged on the semiconductor substrate, having a transistor arranged on the semiconductor substrate, and connected with a first terminal with a first potential, an anti-fuse element connected between a second terminal with a second potential different from the first potential and the transistor, and a noise detection circuit electrically connected with respect to the second terminal, and configured to detect a noise and output a detection signal, the transistor being to be turned off on the basis of the detection signal outputted from the noise detection circuit; and
a recording element arranged on the semiconductor substrate, and for imparting a liquid with an energy and discharging the liquid, wherein
product information of the ink jet recording element substrate is recorded onto the anti-fuse element.

In accordance with the present invention, it is possible to prevent incorrect writing on an anti-fuse element due to noise intrusion in a semiconductor component having the anti-fuse element.

Further features of the present invention will become apparent from the following description of exemplary embodiments with reference to the attached drawings.

### BRIEF DESCRIPTION OF THE DRAWINGS

FIG. 1A is a circuit configuration example in which a memory is protected from an external noise of a semiconductor substrate of Example;

FIG. 1B is a configuration example of a voltage application circuit of Example;

FIG. 1C is a configuration example in which reading and writing of the voltage application circuit of Example are performed;

FIG. 1D is a circuit configuration example in which a memory is protected from an external noise of a semiconductor substrate of Example;

FIG. 1E is a circuit configuration example in which a memory is protected from an external noise of a semiconductor substrate of Example;

FIG. 2A is a graph showing the operation waveform of a noise protection circuit of Example;

FIG. 2B is a graph showing the operation waveform of a noise protection circuit of Example;

FIG. 3 is a device cross sectional structure schematic view of a capacitance and a driving element for executing the present invention;

FIG. 4A is an arrangement example of an ink jet recording element of a memory protection circuit of Example;

FIG. 4B is a substrate arrangement example of an ink jet recording element of a memory protection circuit of Example; and

FIG. 5 is a memory writing circuit configuration example of Comparative Example.

### DESCRIPTION OF THE EMBODIMENTS

Below, referring to the accompanying drawings, preferred embodiments of this invention will be described exemplarily in details. However, for the dimensions, the materials, the shapes, and the relative arrangement of constituent components described in this embodiment, and the like, the scope of this invention is not intended to be limited thereto unless otherwise specified. Further, the materials, the shapes, and the like regarding the members once described in the following description are the same as those in the initial description also in a later description unless otherwise specified. Particularly, it is possible to apply the well-known technology or the known technology in the technical field to the configuration or the step not shown nor described. Further, an overlapping description may be omitted.

### Example 1

### Circuit Configuration

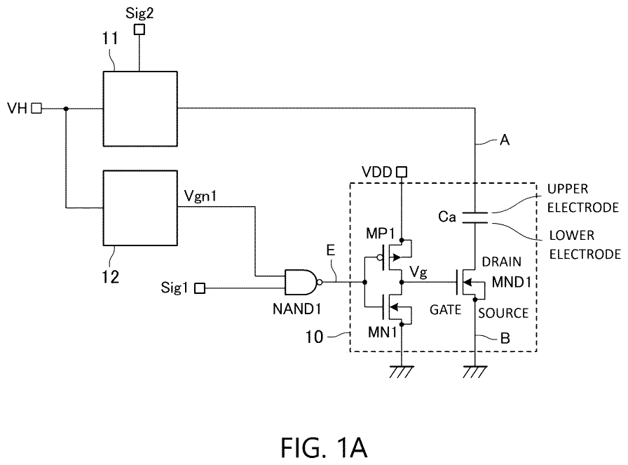

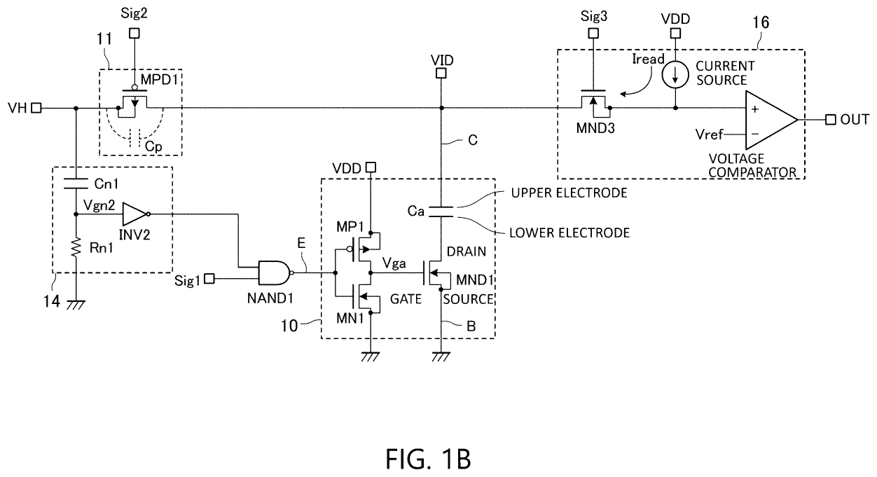

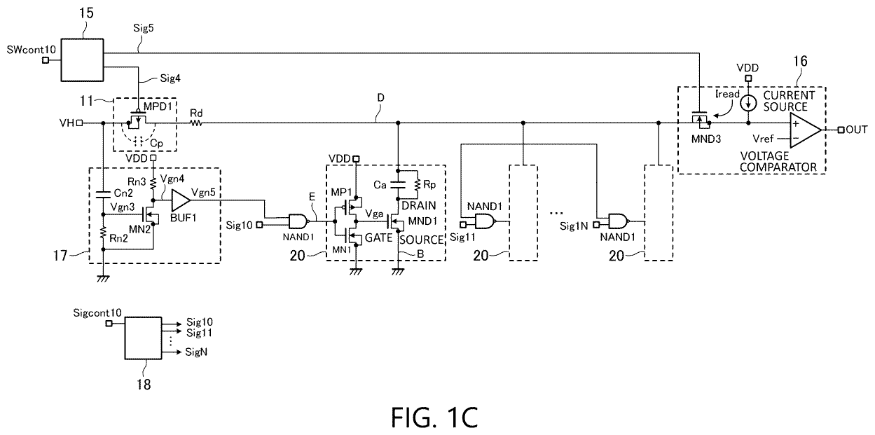

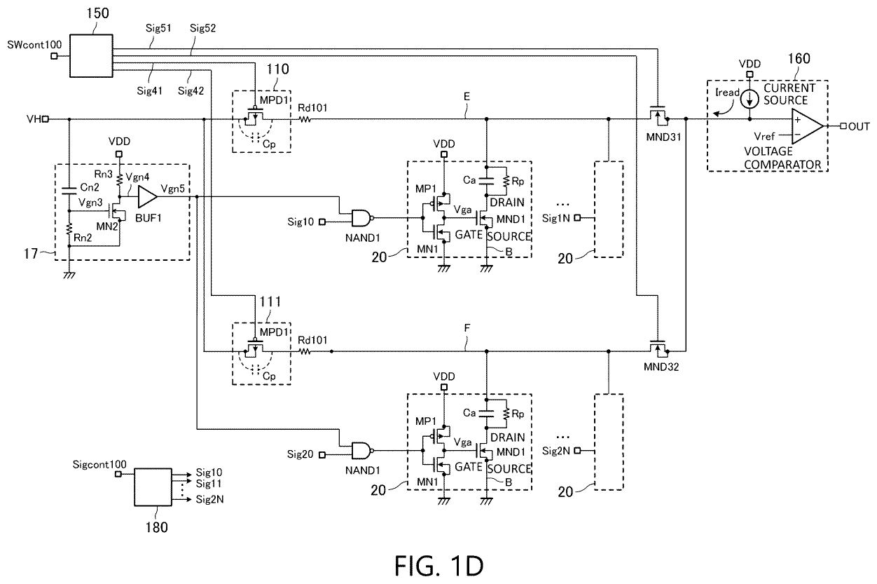

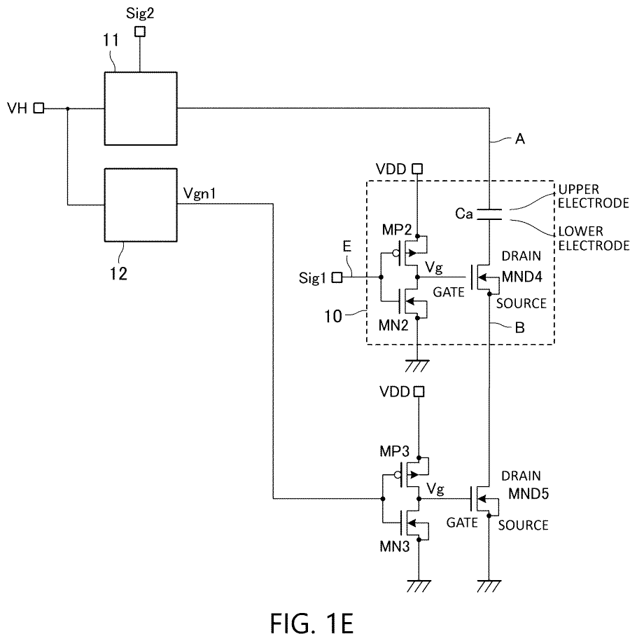

FIG. 1A is one example of the circuit configuration of a semiconductor component, and shows a state before information is written on an anti-fuse element Ca.

A semiconductor component of the present embodiment has a memory portion 10 having a transistor MP1, a transistor MN1, a transistor MND1, and an anti-fuse element Ca. The anti-fuse element Ca is such an element so as to have a first resistance value before information is written, and as to have a second resistance value smaller than the first resistance value after information is written. Namely, the writing operation of information changes the resistance value of the anti-fuse element Ca. A larger first resistance value is more preferable. Ideally, the first resistance value may be infinite. Further, a larger difference between the first resistance value and the second resistance value is more preferable.

The anti-fuse element Ca functions as a capacitance element before information is written, and functions as a resistance element after information writing. FIG. 1A shows the state before information is written on the anti-fuse element Ca. For this reason, the anti-fuse element Ca is indicated with a circuit sign of the capacitance element. Such a configuration enables the anti-fuse element Ca to hold the information written on the basis of a change in resistance value.

In FIG. 1A, a transistor MP1 is a P type transistor, and a transistor MN1 is an N type transistor. Further, to each gate of the transistor MP1 and the transistor MN1, an output signal from a noise detection signal input circuit NAND1 (described later) is inputted.

Further, to the source and the back gate of the transistor MP1, a power supply voltage VDD (e.g., 3.3 V) is supplied, and the drain thereof is connected with the drain of the transistor MN1 and the gate of the transistor MD1. The source and the back gate of the transistor MN1 are connected to a ground GND. The transistor MP1 and the transistor MN1 form a logic circuit (an inverter in FIG. 1A).

The transistor MND1 is an N type high breakdown voltage transistor, and controls the application of a voltage to the anti-fuse element Ca. The transistor MND1 can be formed of, for example, an NMOS transistor. Herein, the high breakdown voltage transistor is a transistor having a higher breakdown voltage than that of a transistor (such as a MP1 or a MN1) for use in a logic circuit. The high breakdown voltage transistor is preferably formed so as to be prevented from being broken even when applied with a large voltage (e.g., 32 V) that the transistor of a general logic circuit such as a control portion cannot withstand. Further, by setting the transistors MP1 and MN1 forming the logic circuit as transistors having a lower breakdown voltage than that of the transistor MND1, it is possible to operate the logic circuit at a high speed.

The anti-fuse element Ca is connected with a wire B via the transistor MND1. As the anti-fuse element Ca, for example, an anti-fuse element having a MOS structure (Metal Oxide Semiconductor structure) can be used. The anti-fuse element Ca is connected with a wire A.

The wire A and the wire B are each a connection portion for electrically connecting a memory portion 10 and an external circuit, and is a terminal for applying a voltage to the anti-fuse element Ca, or measuring the voltage thereof. For example, the electric potential of the wire A can be set at a high voltage (e.g., 32 V) at the time of writing information. The drain of the transistor MND1 is connected with one terminal of the anti-fuse element Ca, and the source of the transistor MND1 is connected to the GND. The other terminal of the anti-fuse element Ca is connected with the wire A. The wire B (first terminal) is set at, for example, grounding potential GND (first potential).

The voltage application circuit 11 is a circuit for switching whether to supply a high voltage (second potential) to be applied to a VH terminal to the wire A on the basis of a control signal Sig2, or not. The VH terminal is, for example, an external connection terminal of 32 V, and corresponds to the second terminal. The voltage application circuit 11 can be configured including, for example, a P type high breakdown voltage MOS transistor MPD1 as shown in FIG. 1B.

The transistor MPD1 may be configured to perform a switching operation on the basis of a control signal Sig4 to be outputted from a writing/reading control circuit 15 separately provided as shown in FIG. 1C. The writing/reading control circuit 15 may include a booster circuit for boosting a logic power supply voltage VDD to the voltage of the control signal Sig4. Further, when the high voltage to be applied to the VH terminal is lower than the write voltage of the anti-fuse element Ca, the voltage application circuit 11 may be configured so as to include a step-down circuit for stepping down the VH voltage (e.g., 32 V) to the write voltage (e.g., 24 V).

At the time of reading whether the anti-fuse element Ca is in a writing state, or not, determination can be performed by detecting the voltage of the VID terminal to be electrically connected with the wire C from the outside of the semiconductor component as shown in FIG. 1B. Alternatively, as shown in the same drawing, the writing state may be detected by a reading circuit 16. When the reading circuit 16 is mounted at the same semiconductor component, the following configuration is preferable: a high breakdown voltage transistor MND3 is connected between the reading circuit 16 and the wire C, so that the reading circuit 16 and the wire C can be electrically separated from each other at other times than the reading time.

As shown in FIG. 1C, for a control signal Sig3 of a transistor MND3, a control signal Sig5 may be outputted from the writing/reading control circuit 15 in synchronization with a control signal Sig4 of the voltage application circuit 11. Incidentally, when the high breakdown voltage MOS transistors MPD1 and MND3 are turned ON at the same time, the voltage outputted from the voltage application circuit 11 and the voltage outputted from the reading circuit 16 may interfere with each other to be caused to malfunction. Further, when the reading circuit 16 is configured of a low breakdown voltage transistor for use in a logic circuit, the high voltage applied from the VH terminal is applied to the low breakdown voltage transistor, which may break the reading circuit 16. For this reason, the writing/reading control circuit 15 is required to be controlled so as to prevent the high breakdown voltage MOS transistors MPD1 and MND3 from being turned ON at the same time.

Then, referring to FIG. 1B, a description will be given to the operation for writing information onto the anti-fuse element Ca. At the time of writing information onto the anti-fuse element Ca, the transistor MPD1 of the voltage application circuit 11 is rendered into the ON state. As a result of this, the high voltage (e.g., 32 V) applied to the VH terminal is applied to the wire C to be connected with the anti-fuse element Ca. At this step, it is necessary to turn off the transistor MND3 for rendering the reading circuit 16 and the wire C into the electrically separated state (Hi impedance).

Then, Hi (e.g., 3.3 V) is inputted to a control signal Sig1 corresponding to the anti-fuse element Ca targeted for writing, so that the transistor MND1 is rendered into the ON state. Herein, the control signal Sig1, and a detection signal Vgn1 to be outputted from a noise detection circuit 12 described later are inputted to the noise detection signal input circuit NAND1. Further, at the normal time other than the noise detection time, Hi is outputted as the detection signal Vgn1. Accordingly, the wire E that is the output from the noise detection signal input circuit NAND1 becomes a Lo level (e.g., the grounding potential), and a signal at a Hi level is outputted from the Vga, so that the transistor MND1 is rendered into the ON state. As a result of this, the high voltage applied to the wire C is applied to the gate insulation film of the anti-fuse element Ca. As a result, the gate insulation film of the anti-fuse element Ca undergoes dielectric breakdown, so that the resistance value of the anti-fuse element Ca largely decreases. Accordingly, before writing, the anti-fuse element Ca was a capacitance element. In contrast, after writing the anti-fuse element Ca becomes a resistance element.

Then, referring to FIG. 1B, a description will be given to the information reading operation when a reading circuit 16 is mounted on the same semiconductor component as that of the anti-fuse element Ca. Before performing information reading, the transistor MPD1 is required to be rendered into the OFF state, so that the VH terminal voltage is required to be in a state electrically separated from the wire C connected with the anti-fuse element Ca (Hi impedance). Further, the transistor MND3 is rendered into the ON state, so that the reading circuit 16 and the wire C are electrically connected with each other.

In this state, the control signal Sig1 corresponding to the anti-fuse element Ca targeted for information reading is set at a Hi level signal, thereby rendering the transistor MND1 into the ON state. As a result of this, a reading current Iread is supplied from the reading circuit 16 to the anti-fuse element Ca. Herein, the reading voltage Vread of Iread×Ra is inputted to a voltage comparator provided in the reading circuit 16 via the wire C, where Ra represents the resistance of the anti-fuse element Ca. The reading voltage Vread is compared with the comparison standard voltage Vref. When the Vread is larger, “High” is outputted to the output terminal OUT. When the Vread is smaller, “Low” is outputted.

The anti-fuse element Ca generally includes an insulation film. For this reason, in the unwritten state, the resistance value increases. When writing is performed, the insulation film is broken, resulting in a conduction state. Accordingly, the resistance value decreases. In the case of the exemplified circuit, “High” is outputted in the unwritten state, and “Low” is outputted in the written state. However, an inverter INV may be added to the OUT output stage for achieving the inverse logic. Incidentally, the configuration of the reading circuit 16 may be other methods than the resistance value detection by the current source mentioned in the present Example.

On the other hand, in the product manufacturing step or under user environment, a very large surge voltage may enter into the semiconductor component from the VH terminal due to static electricity discharge (ESD: Electro-Static Discharge), lightening surge entering the AC 100 V power supply of a building, or the like. Particularly, it is considered as follows: when a surge voltage is applied to the VH terminal despite that the transistor MPD1 shown in FIG. 1B is in the OFF state during information reading, a surge voltage enters the wire C via a parasitic capacitance Cp formed on the semiconductor substrate.

At this step, the transistor MND3 is in the ON state. For this reason, a high voltage surge voltage may be applied to the reading circuit 16 for breakage. Further, at this step, the transistor MND1 is ON, namely, the lower electrode of the anti-fuse element Ca is connected to GND. For this reason, when even a surge voltage as comparatively smaller as the insulation film breakage voltage of the anti-fuse element Ca of about 10 Vis applied to the upper electrode, writing may be performed. As a result, the anti-fuse element Ca not to be written may be written, so that the information recorded in the semiconductor component may be changed. Further, during the electricity measurement in the shipment inspection step of a product, for example, during the soundness confirmation of the anti-fuse element Ca or the operation confirmation of the reading circuit, the same problem may be caused.

### Conventional Configuration

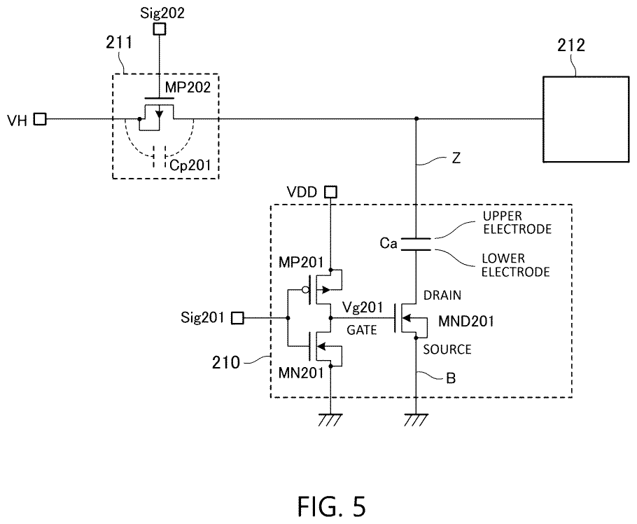

FIG. 5 shows a specific circuit diagram with a conventional configuration. A voltage application circuit 211 generally includes transistors. FIG. 5 particularly shows an example in which the voltage application circuit 211 includes a MOS transistor. By turning off a MOS transistor MP202 at other times than the writing time, the anti-fuse element Ca is electrically separated from the power supply pad VH. For this reason, a different operation from writing, such as reading determination by a separately provided reading circuit 212 can be performed.

Herein, the MOS transistor MP202 can keep the OFF state normally under environment in which the power supply/ground voltage is stable. However, when a high frequency voltage or a surge voltage enters the power supply pad VH due to static electricity discharge received from the outside of the semiconductor component, lightening surge, or the like, a surge voltage may be transmitted therethrough due to the parasitic capacitance Cp201 formed at the MOS transistor MP202, or the like. Particularly when a surge voltage enters to the wire Z at the time of the reading operation, breakage of the reading circuit 212 or incorrect writing on the anti-fuse element Ca may be caused.

### Effect of the Present Configuration

Under such circumstances, in the present invention, as shown in FIG. 1A, a noise detection circuit 12 was connected with the vicinity of the VH terminal into which a noise voltage enters. The noise detection circuit 12 is configured so as to output a detection signal Vgn1 for turning off the transistor MND1 when a noise is detected. The noise detection circuit 12 is arranged at least at a position closer to the VH terminal that is an external connection terminal than the position where the voltage application circuit 11 and the anti-fuse element Ca are arranged in the semiconductor substrate.

In the present Example, the detection signal Vgn1 and the control signal Sig1 are inputted to the noise detection signal input circuit NAND1. The noise detection circuit 12 outputs Hi at the normal time, and outputs Lo at the detection time as the detection signal Vgn1. As a result of this, at the normal time, the reversal data of the control signal Sig1 is inputted to a memory module (memory portion 10), so that the transistor MND1 is controlled according to the control signal Sig1.

On the other hand, the noise detection circuit 12 outputs Lo as the detection signal Vgn1 when the noise voltage which has entered from the VH terminal is detected. Inputting of Lo to one terminal of the noise detection signal input circuit NAND1 results in outputting of Hi to the wire E from the NAND1 circuit irrespective of the voltage of the control signal Sig1. Accordingly, Hi is inputted to the memory portion 10, so that the transistor MND1 is normally in the OFF state.

As a result of this, also when a noise or a surge voltage enters at the time of inputting Hi to the control signal Sig1 for turning on the transistor MND1 in the reading operation of the anti-fuse element Ca, the shipment check step, or the like, the transistor MND1 is turned off. Namely, the lower electrode of the anti-fuse element Ca is rendered into the Hi impedance state. For this reason, a high voltage is not applied to both ends of the anti-fuse element Ca. Accordingly, the writing operation at the timing at which the writing operation onto the anti-fuse element Ca is not expected is suppressed from being carried out. Accordingly, it is possible to suppress a change in information recorded to the semiconductor component at an unexpected timing. Incidentally, herein, the NAND1 was used as the combinational circuit. However, the present invention is not limited thereto, and any combinational circuit may be used so long as it can implement the same function.

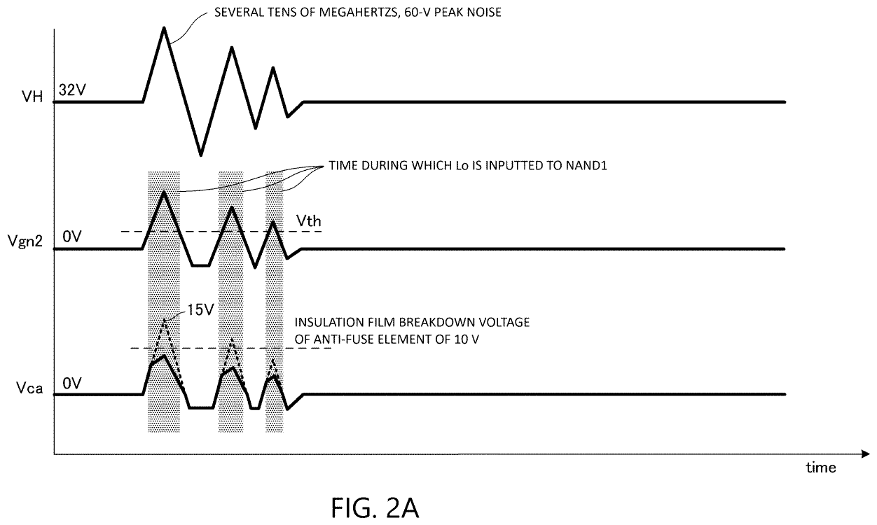

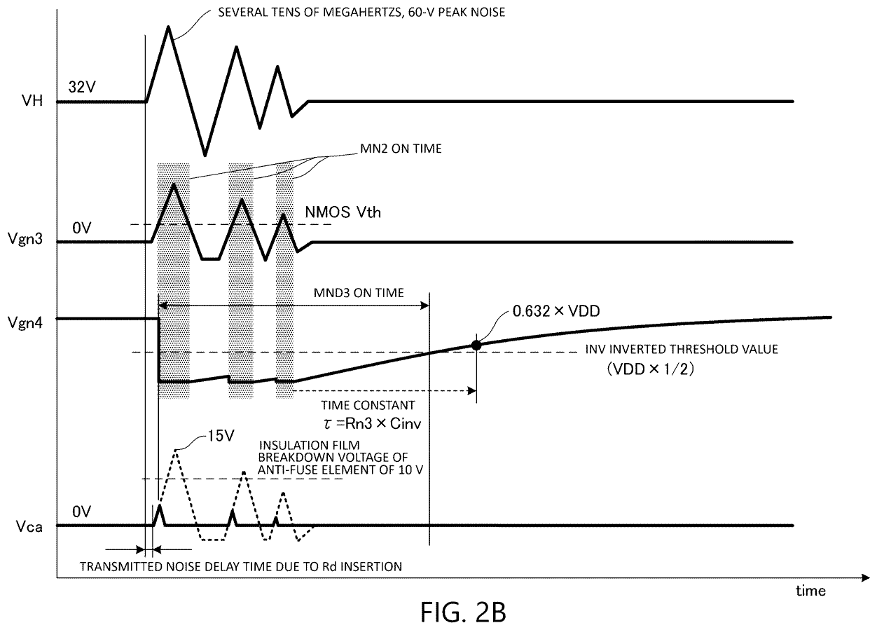

With reference to the circuit diagram of FIG. 1B, a more detailed voltage waveform will be described by reference to FIG. 2A. The noise voltage applied to the VH terminal is indicated with a VH waveform, and each opposite end voltage of the anti-fuse element Ca is indicated with a Vca waveform. To the VH terminal, the voltage as the writing voltage is supplied. The VH terminal is applied with a high voltage (e.g., 32 V) as the steady state. However, at the information reading time, the transistor MPD1 of the voltage application circuit 11 is in the OFF state. For this reason, the voltage value of the wire C becomes 0 V, or the value equal to the reading voltage value of the anti-fuse element Ca.

Herein, it is assumed that the VH terminal is applied with a noise voltage of several tens of megahertzs, 60 V peak. In this case, a high frequency component is transmitted to the wire C via a parasitic capacitance Cp. Herein, when a countermeasure against a noise is not particularly achieved (in the case of the related art), the voltage may reach a voltage of 15 V as indicated with a dotted line of the Vca waveform. When the insulation film breakdown voltage of the anti-fuse element Ca is assumed to be, for example, 10 V (indicated with a broken line for Vca), writing onto the anti-fuse element Ca is performed.

On the other hand, when the countermeasure against a noise as in the present Example is achieved, the high frequency component of the noise voltage is transmitted with respect to the noise detection capacitance Cn1 (capacitance element) in the noise detection circuit 14, so that the voltage increases as with the noise detection signal Vgn2 shown in the Vgn2 waveform of FIG. 2A. Herein, during the period (NAND1 operation time) in which the Vgn2 exceeds the threshold value voltage Vth (indicated with a broken line for Vgn2) of the noise detection signal input circuit NAND1 operation, Lo is inputted to one end of the NAND1. As a result, the transistor MND1 is turned off, and the both end potential difference of the anti-fuse element Ca is suppressed. For this reason, an increase in both end voltages of the anti-fuse element Ca is suppressed as indicated with a solid line for the Vca waveform of FIG. 2A. As a result, the voltage can be kept at the insulation film breakdown voltage of the anti-fuse element Ca of 10 V or lower. Accordingly, it becomes possible to prevent incorrect writing on the anti-fuse element Ca due to the noise voltage entering from the VH terminal.

Incidentally, the noise detection circuit 14 is provided with a pull-down resistance Rn1 (first resistance element) so as to prevent the noise detection signal input circuit NAND1 from operating in the state in which a noise does not enter, namely the voltage stable steady state. Further, a protective diode generally for use as a protective element is preferably connected between VH terminal-GND so as to prevent the element breakdown due to the noise voltage.

Incidentally, as shown in FIG. 1C, it is more preferably configured as follows: a parallel resistance Rp (third resistance element) is connected with respect to the anti-fuse element Ca, thereby preventing information from being incorrectly written onto the anti-fuse element Ca. Specifically, it is possible to prevent the following: when a writing voltage (e.g., 32 V) is applied to the wire D, a high voltage is applied to both ends of the anti-fuse element Ca despite that the memory driving transistor MND1 is in a non-conduction state, resulting in the writing state.

### Cross Sectional Structure

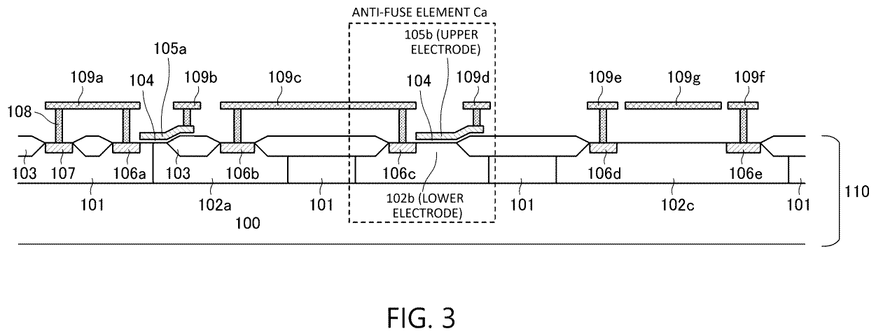

FIG. 3 shows a specific example of the cross sectional structure of a semiconductor substrate 110 including the anti-fuse element Ca, the resistance element Rp, and the transistor MND1 shown in FIG. 1C.

In the semiconductor substrate 110, on a P type silicon substrate 100, a P well region 101, and N well regions 102a and 102b, and 102c are formed. The P well region 101 can be formed by the same step as that for the P well of the NMOS transistor configuring the logic circuit. Further, the N well regions 102a, 102b, and 102c can be formed by the same step as that for the N well of the PMOS transistor configuring the logic circuit.

Incidentally, the impurity concentration of the N well region with respect to the P type silicon substrate 100 is the concentration such that each breakdown voltage of the N well regions 102a, 102b, and 102c, and the P type silicon substrate 100 becomes higher than a high voltage VID. Further, each impurity concentration of the P well region 101 and the N well regions 102a, 102b, and 102c is the concentration such that each breakdown voltage of the P well region 101 and the N well regions 102a and 102b becomes higher than the high voltage VID.

In the P well region 101 and the N well regions 102a, 102b, and 102c, a field oxide film 103, high concentration N type diffusion regions 106a to 106e, and a high concentration P type diffusion region 107 are formed. The field oxide film 103 can be formed by, for example, the LOCOS (Local Oxidation of Silicon) method.

A description will be given to the configuration of the transistor MND1 that is a high breakdown voltage NMOS transistor. The gate electrode 105a is arranged on the P well region 101 and the N well region 102a adjacent via the gate insulation film 104. The region where the P well region 101 and the gate electrode 105a overlap becomes a channel formation region.

The high concentration N type diffusion region 106a is the source of the transistor MND1, and the high concentration P type diffusion region 107 is a back gate electrode. The N well region 102a has a portion extending to the underlying portion of the gate electrode 105a as the electric field relaxation region of the drain. The high concentration N type diffusion region 106b formed in the N well region 102a becomes the drain electrode of the transistor MND1.

Further, the transistor MND1 has a structure in which the drain side of the gate electrode 105a extends on the field oxide film 103 formed in the N well region 102, a so-called LOCOS offset structure. As a result of this, it is possible to ensure the gate-drain breakdown voltage even when the transistor MND1 is rendered into the OFF state, namely, the state in which the voltage of the gate electrode is GND, and the voltage of the drain electrode has increased to the high voltage VID.

Then, the structure of the anti-fuse element Ca will be described. The anti-fuse element Ca has an upper electrode, a lower electrode, and an insulation layer therebetween. For example, the electrode 105b provided on the N well region 102b via a gate insulation film 104 functions as the upper electrode of the anti-fuse element Ca. Further, in the N well region 102b, the portion connected with the high concentration N type diffusion region 106c, and overlapping the upper electrode in a plan view with respect to the surface to be provided with elements such as the transistor MND1 of the semiconductor substrate 110 functions as the lower electrode. Incidentally, the plan view with respect to the surface to be provided with the elements such as the transistor MND1, the anti-fuse element Ca, and the resistance element Rp is, for example, the plan view with respect to the surface of the channel formation region of the transistor MD1.

In the drawing, a high concentration N type diffusion region 106c is formed only in the region of the N well region 102b not overlapping the upper electrode in a plan view. However, the arrangement of the high concentration N type diffusion region 106c is not limited thereto. For example, the high concentration N type diffusion region 106b may be formed in a part of the overlapping portion with the upper electrode, or the entire region of the overlapping portion thereof. When the high concentration N type diffusion region 106c is also formed in the region overlapping the upper electrode in a plan view, the overlapping portion of the high concentration N type diffusion region 106c also functions as the lower electrode of the anti-fuse element Ca.

Further, in the drawing, the lower electrode of the anti-fuse element Ca is connected with the drain of the transistor MND1. However, the upper electrode may be connected with the drain of the third transistor MND1, and the lower electrode may be connected with a high voltage (the wire A shown in FIG. 1A).

The gate insulation film 104 can be formed by the formation step of each gate insulation film of the transistors MP1 and MN1 configuring the logic circuit. For the materials for the gate insulation film 104, for example, an oxide film can be used. Further, the electrodes 105a and 105b can be formed as, for example, a polysilicon layer. The polysilicon layer, the high concentration N type diffusion regions 106a to 106c, and the high concentration P type diffusion region 107 can be formed by the same step of each element of the transistors MP1 and MN1 configuring the low breakdown voltage logic circuit.

Thus, the anti-fuse element Ca is a capacitance element having a MOS structure, and the transistor controlling writing onto the anti-fuse element Ca is a MOS transistor. Accordingly, the anti-fuse element Ca and the transistor can be formed by the same step. For this reason, a semiconductor component can be formed with a small number of steps at a low cost.

An insulation film provided with a plurality of contact portions 108 is provided on the high concentration P type diffusion region 107, the N type diffusion regions 106a to 106e, and the field oxide film 103. On the insulation film, conductive layers 109a to 109e are provided. The conductive layers 109a to 109e can be formed of, for example, a metal such as aluminum. Incidentally, the conductive layers 109a to 109e and each electrode, and wire have no restriction on the manufacturing procedure, the materials, and the structure so long as they are electrically connected.

In the drawing, as the anti-fuse element Ca, a capacitance element including the lower electrode and the upper electrode formed of an N well region and polysilicon, respectively, is shown as an example. However, the anti-fuse element Ca is not limited to this structure, and may be, for example, a capacitance element using a PMOS transistor. It is essential only that one of the lower electrode and the upper electrode of the anti-fuse element Ca functions as one terminal, and the other functions as the other terminal.

A resistance element Rp has an N well region 102c that is the semiconductor region in the semiconductor substrate 110, and is connected to the conductive layers 109d and 109e via the high concentration N type diffusion regions 106d and 106e, respectively. However, the resistance element Rp is not limited to such a structure of a common diffusion resistance. For example, a resistance element of a conductive layer, or a resistance element of polysilicon may be used as the resistance element Rp.

The insulation film is an insulator layer formed on the semiconductor substrate 110 so as to cover the transistor MND1, the resistance element Rp, and the like, and is formed of, for example, silicon oxide. Further, the insulator layer is not limited thereto, may be formed of silicon nitride or silicon carbide, and may be a lamination layer or a mixture layer thereof.

The conductive layer 109a is connected with the source and the back gate of the transistor MND1 via the contact portion 108, and is given a grounding potential. The conductive layer 109b is connected with the drain electrode of the transistor MND1 and the lower electrode of the anti-fuse element Ca via the contact portion 108. The conductive layer 109c is connected with the upper electrode of the anti-fuse element Ca via the contact portion 108, and is connected with the wire A shown in FIG. 1A at a portion not shown. The conductive layer 109c is applied with a high voltage (e.g., 32 V) via the wire A at the time of writing. The conductive layer 109d is connected with the conductive layer 109c (not shown), and the conductive layer 109e is connected with the conductive layer 109b (not shown).

### Example 2

Subsequently, Example 2 will be described. The same configuration as that of Example 1 is given the same numeral and sign, and the description thereon is simplified. A noise detection circuit 17 of the present Example drives the noise detection signal input circuit with more stability, thereby suppressing an increase in both end voltages of the anti-fuse element Ca with efficiency.

In the noise detection circuit 17 shown in FIG. 1C, a signal from the noise detection capacitance Cn2 is inputted to the transistor MN2. The signal resulting from a voltage Vgn4 obtained by dividing the logic power supply voltage VDD by a pull-up resistance Rn3 (fourth resistance element) and the transistor MN2 (third transistor) which has passed through a buffer circuit BUF1 is outputted as a voltage Vgn5. In the present Example, it is configured such that the noise detection signal input circuit NAND1 is driven according to the output from the voltage Vgn5.

A detailed voltage waveform will be described with reference to FIG. 2B. The noise voltage applied to the VH terminal is indicated with a VH waveform. A voltage as the writing voltage is supplied to the VH terminal. The VH terminal is applied with a high voltage (e.g., 32 V) as the steady state. However, at the time of information reading, the transistor MPD1 of the voltage application circuit 11 is in the OFF state. For this reason, the voltage value of the wire D is 0 V, or the value equal to the reading voltage value of the anti-fuse element Ca.

Herein, it is assumed that the VH terminal is applied with a noise voltage of several tens of megahertzs, 60 V peak. In this case, the high frequency component is transmitted to the wire D via the parasitic capacitance Cp. Herein, when a countermeasure against a noise is not particularly achieved (in the case of the related art), the voltage may reach up to a voltage of 15 V as indicated with a dotted line of a Vca waveform. When the insulation film breakdown voltage of the anti-fuse element Ca is assumed to be, for example, 10 V (indicated with a broken line for Vca), writing is performed onto the anti-fuse element Ca.

On the other hand, in the case where the countermeasure against a noise is achieved as in the present Example, a high frequency component of a noise voltage is transmitted with respect to the noise detection capacitance Cn2 in the noise detection circuit 17, and increases in voltage as with the noise detection signal Vgn3 waveform of FIG. 2B. Herein, during the period (MN2 ON time) in which the Vgn3 exceeds the threshold value voltage Vth of the transistor MN2, the MN2 is turned on.

When the MN2 is turned on, the voltage Vgn4 of the BUF1 input end becomes 0 V, namely, the voltage Vgn4 of the noise detection signal input circuit NAND1 input end becomes 0 V. For this reason, the output from the noise detection signal input circuit NAND1 becomes hi, and the transistor MND1 is turned off, so that an increase in both end voltages of the anti-fuse element Ca is suppressed. Immediately thereafter, the noise voltage falls. For this reason, the Vgn3 also falls. Subsequently, the transistor MN2 is turned off. However, the time proportional to the time constant τ=Rn3×Cinv determined by the pull-up resistance Rn3 and the capacitance CinV (not shown) added to the gate of BUF1 is required for the input voltage Vgn4 of the BUF1 to undergo transition from the 0 V state to the VDD voltage. The Vng4 is required to exceed the threshold value voltage (about ½ of the VDD voltage) for logic inversion of the BUF1. For this reason, during the period in which the Vng4 does not exceed this value, Lo continues to be inputted to the noise detection signal input circuit NAND1. For this reason, the transistor MND1 being OFF is kept, so that an increase in both end voltages of the anti-fuse element Ca can continue to be suppressed.

As an example, when it is assumed that pull-up resistance Rn3=100 kΩ, and addition capacitance Cinv=1 pF, it results that time constant τ=1 μsec. Accordingly, the time until the BUF1 is inverted is about 0.7 μsec. During the period, it is possible to continue to input Lo to the noise detection signal input circuit NAND1. During the period, for the both end voltages Vca of the anti-fuse element Ca, an increase in voltage can be suppressed as indicated with a solid line. For this reason, the voltage can be kept equal to or lower than the insulation film breakdown voltage of the anti-fuse element Ca of 10 V or lower. Accordingly, it becomes possible to prevent incorrect writing on the anti-fuse element Ca caused by the noise voltage entering from the VH terminal.

Further, during the period until the time when the noise detection circuit 17 detects a noise, the noise detection signal input circuit NAND1 shows Lo, and the transistor MND1 is turned off, the noise voltage may be transmitted through the voltage application circuit 11 to reach the wire D. For this reason, the following configuration is preferable: as shown in FIG. 1C, a noise delay resistance Rd (second resistance element) is inserted to the output end of the voltage application circuit 11, thereby delaying the noise to the wire D as indicated with the Vca waveform of FIG. 2B; and before the increase in voltage of Vca becomes high, the transistor MND1 is turned off. The noise delay resistance Rd may exert influences including a decrease in voltage or imposition of a writing current restriction at the time of writing on the anti-fuse element Ca. For this reason, about several tens of ohms exerting less influences thereof is preferable. The noise delay resistance Rd is a relatively smaller resistance value, and hence can be formed with a polysilicon layer or high concentration N type diffusion.

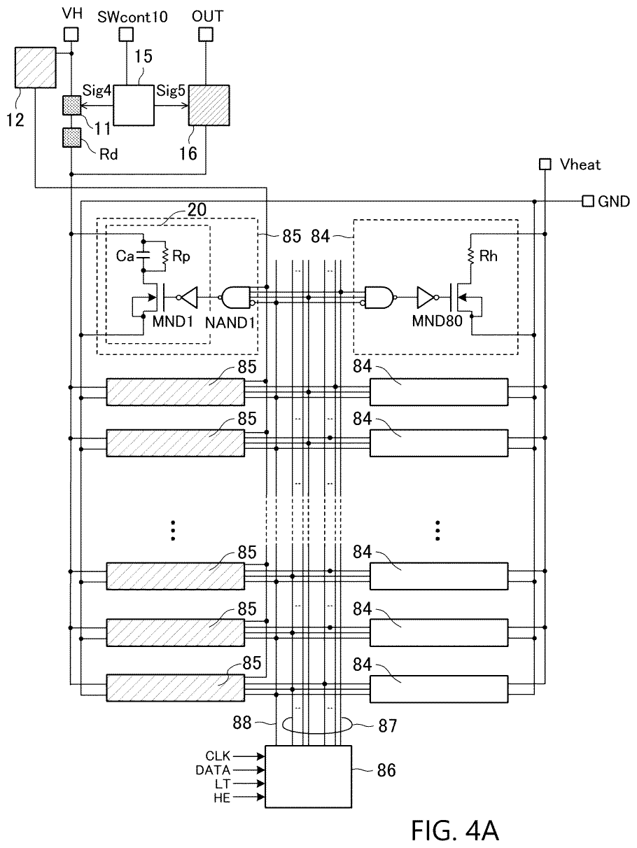

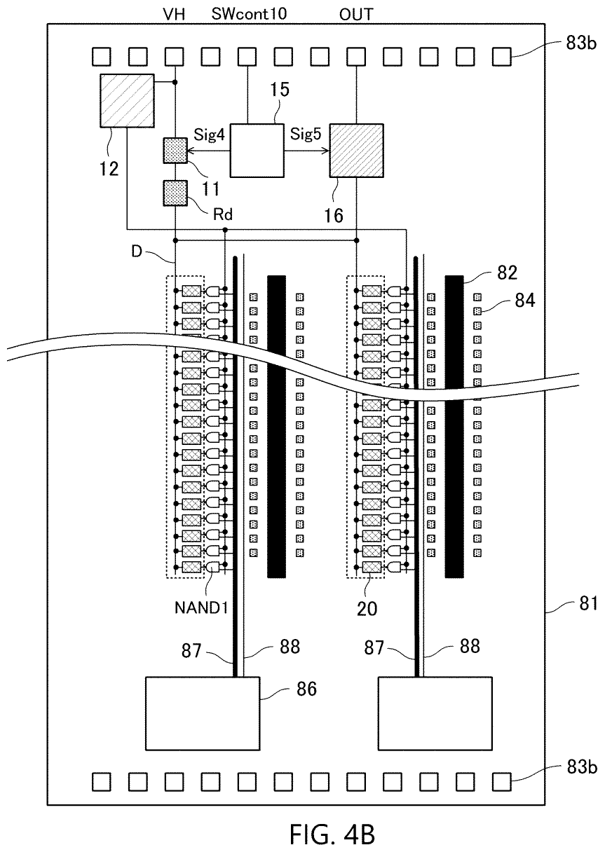

FIG. 4A shows a connection diagram of a recording element Rh, the anti-fuse element Ca, and a selection circuit 86 when the circuit of the present embodiment is mounted on an ink jet recording element substrate. Operation is performed so that the recording element Rh or the anti-fuse element Ca is exclusively selected according to the logic state of a function selection signal 88 that is an output signal from the selection circuit 86. For specific bit selection, selection is carried out according to a bit selection signal 87 that is an output signal from the selection circuit 86. For the transmission of the bit selection signal 87, a common signal line is used at the recording element Rh and the anti-fuse element Ca.

The output of the noise detection circuit 12 is connected with one terminal of the NAND1 of the circuit 85 formed of the memory portion 20 (memory module) and an input NAND1 circuit, and a voltage application circuit 11 is set between the memory portion 20 and the VH terminal.

FIG. 4B shows an example in which the circuit of the present embodiment is arranged at a recording element substrate 81 of an ink jet system. The recording element substrate 81 has an ink feeding port 82 for supplying a liquid such as an ink, an external connection terminal 83, and a recording element 84. The recording element substrate 81 can be preferably used for an ink jet system recording device (liquid discharge device). By using such a recording element substrate 81, the anti-fuse element can be used as an OTP memory for recording product information such as a chip ID or a setting parameter after completion of the product. The recording element 84 has a functional portion such as a heat generation element or a piezoelectric element, and imparts a liquid such as an ink with an energy for discharge, thereby performing recording.

In the recording element substrate 81, the memory portion 20 and the noise detection signal input circuit NAND1 are arranged in parallel with the direction in which the recording elements 84 are arrayed. The noise detection circuit 12 and the voltage application circuit 11 are arranged in the region between the array group of the external connection terminals 83 and the array group of the recording elements 84. The aspect shown in FIGS. 4A and 4B can provide the foregoing effects. However, the arrangement on the substrate is not limited thereto.

The noise detection circuit 17 is preferably arranged in the vicinity of the VH terminal that is an external connection terminal so that a noise voltage can be detected with good responsiveness and high sensitivity, and more preferably is arranged adjacent to the VH terminal. Further, the selection circuit 86 is arranged in the region between the external connection terminal 83 array group and the recording element Rh array group. By the arrangement according to the same drawing, the symmetry of the outward shape of the ink jet recording element substrate can be kept as much as possible, and the region for wire connection in the substrate can be set smaller.

### Example 3

The present Example shows an example where a plurality of the voltage application circuits shown in the embodiment are arranged. The same configuration as that of each of the Examples is given the same numeral and sign, and a description thereon is simplified.

FIG. 1D is a circuit diagram of a semiconductor component in accordance with the present Example. The semiconductor component has a plurality of memory portions 20 including a capacitance element that is an anti-fuse element Ca, a parallel resistance Rp, and a transistor MND1. A wire E and a wire F are electrically separated from each other. Respective wires have their respective connection switches MND31 and MND32 between their respective voltage application circuits 11 and 111, and their respective noise detection signal input circuits NAND1 and NAND2, and a reading circuit 160, respectively.

A noise detection signal Vgn5 that is an output signal of the noise detection circuit 17 outputs Lo, and Lo is inputted to the noise detection signal input circuits NAND1 and NAND2, respectively. As a result, the outputs from the NAND1 and NAND2 circuits become Hi irrespective of the voltages of the control signals Sig10 and Sig20. Accordingly, Hi is inputted to the memory portion 20, so that the transistor MND1 is normally in the OFF state.

In the present embodiment, two voltage application circuits are provided. For this reason, writing can be performed onto the anti-fuse element Ca with stability, so that the writing time can be shortened. Incidentally, in the present embodiment, the example of the semiconductor component having two voltage application circuits was shown for description. However, when the writing time onto the anti-fuse element Ca within a single time was desired to be more shortened, a larger number of voltage application circuits may be included. Similarly, when the reading time of the anti-fuse element Ca within a single time is desired to be more shortened, a plurality of reading circuits may be included. The configuration of the present Example enables prevention of incorrect writing onto the anti-fuse element Ca from the noise voltage from the VH terminal.

### Example 4

Subsequently, Example 4 will be described. The same configuration as that of each of the Examples is given the same numeral and sign, and a description thereon will be simplified.

In the present Example, as shown in FIG. 1E, on the side of one terminal of the anti-fuse element Ca, a high breakdown voltage transistor MND4 controlled by only a control signal Sig1, and a high breakdown voltage transistor MND5 controlled by only a detection signal Vgn1 are connected in series. The transistor MND4 corresponds to the second transistor, and the transistor MND5 corresponds to the first transistor. The transistors MND4 and MND5 are connected with transistors MP2/MN2 and MP3/MN3 each with a lower breakdown voltage, respectively, thereby forming an inverter of the logic circuit. It is configured such that a control signal Sig1 is inputted to each gate of the transistor MP2 and the transistor MN2, and such that a detection signal Vgn1 is inputted to each gate of the transistor MP3 and the transistor MN3.

At the normal time, for the detection signal Vgn1, Lo (Hi in Example 1) is outputted, so that the transistor MND5 is turned on. On the other hand, at the time of noise detection, for the detection signal Vgn1, Hi (Lo in Example 1) is outputted, so that the transistor MND5 is turned off. Further, the transistor MND4 is turned on/off in response to the control signal Sig1. Namely, at the normal time, the anti-fuse element Ca is read or written in response to the control signal Sig1. At the time of noise detection, the transistor MND5 is turned off. For this reason, reading from and writing onto the anti-fuse element Ca are not performed irrespective of the value of the control signal Sig1.

### Modified Example

Further, in the aspect in which a plurality of the anti-fuse elements Ca are arranged as shown in FIGS. 1C and 1D, the GNDs connected to the source sides of respective memory driving transistors MND1 can be bundled into one. Then, the bundled lines can be connected in common to the drain side of one high breakdown voltage transistor MND controlled only by the noise detection signal Vgn1. In the aspect using the NAND circuit shown in Examples 1 to 3, the NAND circuit is required to be set with respect to each anti-fuse element Ca. In contrast, in the present aspect, one high breakdown voltage transistor MND can control reading and writing of all the anti-fuse elements Ca.

In Examples 1 to 3 described up to this point, assuming that a noise voltage enters from the VH terminal, the noise detection circuit 12 was provided by being connected with the vicinity of the VH terminal. However, the present invention is not limited thereto, and a logic power supply terminal or an external connection terminal exclusively for noise detection may be provided. Alternatively, each number of the noise detection terminals and the noise detection circuits is not limited to one, and may be plural.

As described up to this point, in accordance with each Example of the present invention, a noise detection circuit is arranged in the vicinity of the external connection terminal serving as the noise entering end, and the noise detection circuit detects a noise. As a result, by outputting a control signal for turning off the anti-fuse driving transistor, it is possible to prevent incorrect writing. Therefore, it is possible to suppress incorrect writing caused by an external noise or the like entering via the anti-fuse writing circuit.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2023-209476, filed on Dec. 12, 2023, which is hereby incorporated by reference wherein in its entirety.

What is claimed is:

1. A semiconductor component comprising:
a semiconductor substrate;
a transistor arranged on the semiconductor substrate, and connected with a first terminal with a first potential;
an anti-fuse element connected between a second terminal with a second potential different from the first potential and the transistor; and
a noise detection circuit electrically connected with respect to the second terminal, and configured to detect a noise and output a detection signal, wherein
the transistor is turned off on the basis of the detection signal outputted from the noise detection circuit.

2. The semiconductor component according to claim 1, further comprising a combinational circuit configured to be inputted the detection signal outputted from the noise detection circuit and a control signal of the anti-fuse element, and, output a control signal of the transistor for turning off the transistor when the noise detection circuit detects a noise.

3. The semiconductor component according to claim 2, wherein
the combinational circuit turns off the transistor when the detection signal outputted from the noise detection circuit exceeds a threshold value voltage.

4. The semiconductor component according to claim 1, wherein
the transistor includes a first transistor and a second transistor connected in series,
the first transistor is a transistor to be turned off when the noise detection circuit detects a noise, and
the second transistor is a transistor to be controlled by a control signal of the anti-fuse element.

5. The semiconductor component according to claim 1, wherein
the noise detection circuit includes a capacitance element and a first resistance element connected in series between the second terminal and the first terminal, and outputs a voltage between the capacitance element and the first resistance element as the detection signal.

6. The semiconductor component according to claim 1, further comprising a voltage application circuit configured to supply a voltage to the anti-fuse element from the second terminal.

7. The semiconductor component according to claim 6, wherein
the voltage application circuit supplies a writing voltage of the anti-fuse element.

8. The semiconductor component according to claim 6, wherein
a second resistance element for delaying a noise is connected in series with an output end of the voltage application circuit.

9. The semiconductor component according to claim 6, wherein
the voltage application circuit includes a P type high breakdown voltage MOS transistor.

10. The semiconductor component according to claim 6, wherein
the noise detection circuit is arranged at a position closer to the second terminal than a position at which the voltage application circuit and the anti-fuse element are arranged in the semiconductor substrate.

11. The semiconductor component according to claim 6, comprising a plurality of the voltage application circuits.

12. The semiconductor component according to claim 1, further comprising a third resistance element connected in parallel with the anti-fuse element between the second terminal and the transistor.

13. The semiconductor component according to claim 12, wherein
the third resistance element is a common diffusion resistance.

14. The semiconductor component according to claim 5, wherein
the noise detection circuit further has a fourth resistance element and a third transistor connected with the first terminal, and
the third transistor is turned on based on a voltage between the capacitance element and the first resistance element.

15. The semiconductor component according to claim 1, further comprising a reading circuit configured to read a written state of the anti-fuse element.

16. An ink jet recording element substrate comprising:
a semiconductor substrate;
a semiconductor component arranged on the semiconductor substrate, having a transistor arranged on the semiconductor substrate, and connected with a first terminal with a first potential, an anti-fuse element connected between a second terminal with a second potential different from the first potential and the transistor, and a noise detection circuit electrically connected with respect to the second terminal, and configured to detect a noise and output a detection signal, the transistor being to be turned off on the basis of the detection signal outputted from the noise detection circuit; and
a recording element arranged on the semiconductor substrate, and for imparting a liquid with an energy and discharging the liquid, wherein
product information of the ink jet recording element substrate is recorded onto the anti-fuse element.
